(19) United States
(12) Patent Application Publication
(10) Pub. No.: US 2015/0076542 A1
(43) Pub. Date: Mar. 19, 2015

(54) LIGHT EMITTING MODULE

(71) Applicant: Lextar Electronics Corporation, Hsinchu (TW)

(72) Inventors: Chia-Ming SUNG, Zhubei City (TW); Liang-Ta LIN, Guishan Township (TW); Ching-Yao LIN, New Taipei City (TW); Sheng-Pei LIN, Zhubei City (TW)

(73) Assignee: Lextar Electronics Corporation, Hsinchu (TW)

(21) Appl. No.: 14/197,648

(22) Filed: Mar. 5, 2014

(30) Foreign Application Priority Data
Sep. 14, 2013 (TW) 102133407

(51) Int. Cl. H01L 33/50; H01L 33/56

(52) U.S. Cl. CPC H01L 33/504; H01L 33/56
USPC 257/98

(57) ABSTRACT

The present disclosure provides a light emitting module, which includes a base board, a light emitting diode chip, a transparent thermoplastic layer, and fluorescent glue. The base board includes a die-bonding zone. The light emitting diode chip is bonded on the die-bonding zone. The light emitting diode chip includes an upper surface, a lower surface opposite to the upper surface, and a plurality of side surfaces adjoined between the upper surface and lower surfaces. A transparent thermoplastic layer encloses at least one portion of the light emitting diode chip. The fluorescent glue disposed over to cover the base board, the light emitting diode chip, and the transparent thermoplastic layer.

### RELATED APPLICATIONS

This application claims priority to Taiwan Application Serial Number 102133407, filed Sep. 14, 2013, which is herein incorporated by reference.

### BACKGROUND

1. Technical Field

The present disclosure relates to a light emitting module.

2. Description of Related Art

A conventional light emitting module undergoes a curing process after a die-bonding process. The curing process often results in a peeling-off phenomenon due to high temperature. FIG. 1 is a cross-sectional view showing the peeling-off phenomenon of a conventional light emitting module. During the curing process, fluorescent glue 800 is heated and expands toward a direction 700. Because an adhesion force between the fluorescent glue 800 and a chip 900 is generally greater than that between the chip 900 and a bonding layer 920, when the fluorescent glue 800 expands toward the direction 700, the fluorescent glue 800 pulls the chip 900 to move toward the direction 700. As a result, the chip 900 peels off from the bonding layer 920, and a gap 600 is formed therebetween. Thus, the light emitting module is scrapped and cannot be reworked.

### SUMMARY

The present disclosure provides a light emitting module including a base board, a light emitting diode chip, a transparent thermoplastic layer, and fluorescent glue. The base board includes a die-bonding zone, which is predetermined. The light emitting diode chip is bonded on the die-bonding zone. The light emitting diode chip includes an upper surface, a lower surface opposite to the upper surface, and a plurality of side surfaces adjoined between the upper surface and lower surfaces. A transparent thermoplastic layer encloses at least one portion of the light emitting diode chip. The fluorescent glue disposed over to cover the base board, the light emitting diode chip, and the transparent thermoplastic layer.

In an embodiment of the present disclosure, the base board is a metal frame.

In an embodiment of the present disclosure, the light emitting module further includes a package cup body partially enclosing the metal frame, and exposing a part of a surface of the metal frame. The part of the surface of the metal frame being configured to be the die-bonding zone.

In an embodiment of the present disclosure, the light emitting module further includes a bonding material configured to bond the light emitting diode chip on the die-bonding zone. The bonding material includes tin, copper-tin alloy, or gold-tin alloy.

In an embodiment of the present disclosure, when the light emitting diode chip is bonded on the die-bonding zone through the upper surface, the transparent thermoplastic layer fully encloses the lower surface and the side surfaces of the light emitting diode chip. When the light emitting diode chip is bonded on the die-bonding zone through the lower surface, the transparent thermoplastic layer fully encloses the upper surface and the side surfaces of the light emitting diode chip.

In an embodiment of the present disclosure, when the transparent thermoplastic layer partially encloses the light emitting diode chip, the transparent thermoplastic layer is coated at a junction of the base board and at least one of the side surfaces of the light emitting diode chip. Therefore, at least one portion of a bottom edge of the at least one of the side surfaces and a surface of the base board adjacent to the bottom edge are enclosed by the transparent thermoplastic layer.

In an embodiment of the present disclosure, the package cup body is made of a thermoplastic material or a thermoset material.

In an embodiment of the present disclosure, the thermoplastic material is polycarbonate, polyethylene, polyethylene terephthalate, polybutylene terephthalate, poly 1,4-cyclohexylene dimethylene terephthalate, polycarbonate, polypropylene, nylon, or combinations thereof.

In an embodiment of the present disclosure, the thermoset material is silicone, epoxy, acrylate, acrylic, or combinations thereof.

In an embodiment of the present disclosure, the transparent thermoplastic layer is polycarbonate, polyethylene, polyethylene terephthalate, polybutylene terephthalate, poly 1,4-cyclohexylene dimethylene terephthalate, polycarbonate, polypropylene, nylon, or combinations thereof.

In an embodiment of the present disclosure, the fluorescent glue includes fluorescent powder and a thermoplastic of silicone, epoxy, acrylate, acrylic, or combinations thereof.

In an embodiment of the present disclosure, the fluorescent glue further includes a light scattering material having less than 0.1 wt % of one of titanium dioxide, silica, zinc oxide, alumina, or combination thereof.

Accordingly, the light emitting module of the disclosure includes the transparent thermoplastic layer. When the light emitting module goes through a curing process, the fluorescent glue expands upward. In the meantime, the transparent thermoplastic layer is softened by heat, such that the transparent thermoplastic layer becomes a buffer layer between the fluorescent glue and the light emitting diode chip. When the fluorescent glue expands upward, the light emitting diode chip will not be pulled upward due to the buffer layer, thus preventing a peeling-off phenomenon. As a result, the production yield is increased and the production cost is decreased.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a cross-sectional view showing a peeling-off phenomenon of a conventional light emitting module;

FIG. 2 illustrates a cross-sectional view of a light emitting module according to an embodiment of the present disclosure;

FIG. 3 illustrates a cross-sectional view of a light emitting module according to another embodiment of the present disclosure;

FIG. 4 illustrates a top view of a light emitting module according to an embodiment of the present disclosure;

FIG. 5 illustrates a top view of a light emitting module according to another embodiment of the present disclosure;

FIG. 6 illustrates a top view of a light emitting module according to another embodiment of the present disclosure;

FIG. 7 illustrates a top view of a light emitting module according to another embodiment of the present disclosure;

FIG. 8 illustrates a top view of a light emitting module according to another embodiment of the present disclosure;

FIG. 9 illustrates a top view of a light emitting module according to another embodiment of the present disclosure;

FIG. 10 illustrates a top view of a light emitting module according to another embodiment of the present disclosure;

FIG. 11 illustrates a top view of a light emitting module according to another embodiment of the present disclosure; and

FIG. 12 illustrates a top view of a light emitting module according to another embodiment of the present disclosure.

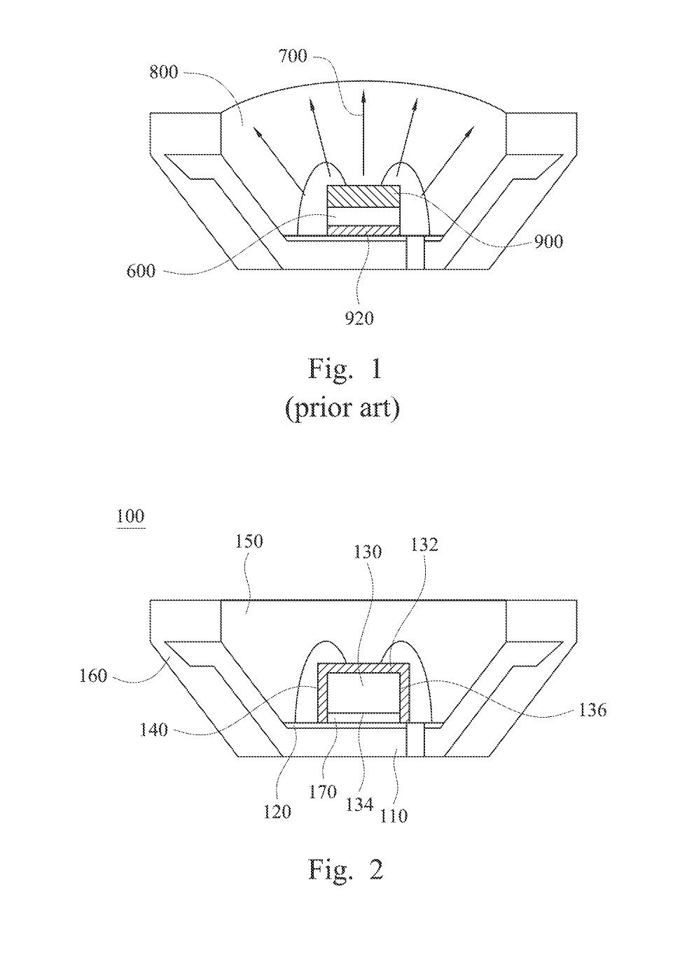

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In order to solve the peeling-off problem of the conventional light emitting module, the disclosure provides a light emitting module to effectively improve the problem. FIG. 2 illustrates a cross-sectional view of a light emitting module 100 according to an embodiment of the present disclosure. The disclosure provides the light emitting module 100 including a base board 110, a light emitting diode chip 130, a transparent thermoplastic layer 140, and fluorescent glue 150. The base board 110 includes a die-bonding zone 120. The light emitting diode chip 130 is bonded on the die-bonding zone 120. The light emitting diode chip 130 includes an upper surface 132, a lower surface 134 opposite to the upper surface 132, and side surfaces 136 adjoined between the upper surface 132 and the lower surface 134. The transparent thermoplastic layer 140 encloses at least one portion of the light emitting diode chip 130. The fluorescent glue 150 is disposed over to cover the base board 110, the light emitting diode chip 130, and the transparent thermoplastic layer 140. The base board 110 is a metal frame. The light emitting module 100 further includes a package cup body 160 partially enclosing the metal frame and exposing a portion of a surface of the metal frame. The portion of the surface of the metal frame is configured as the die-bonding zone 120. A bonding material 170 is disposed below the light emitting diode chip 130 to bond the light emitting diode chip 130 on the die-bonding zone 120. The bonding material 170 may include tin, copper-tin alloy, or gold-tin alloy. When the light emitting diode chip 130 is bonded on the die-bonding zone 120 through the lower surface 134, the transparent thermoplastic layer 140 entirely encloses the upper surface 132 and the side surfaces 136 of the light emitting diode chip 130.

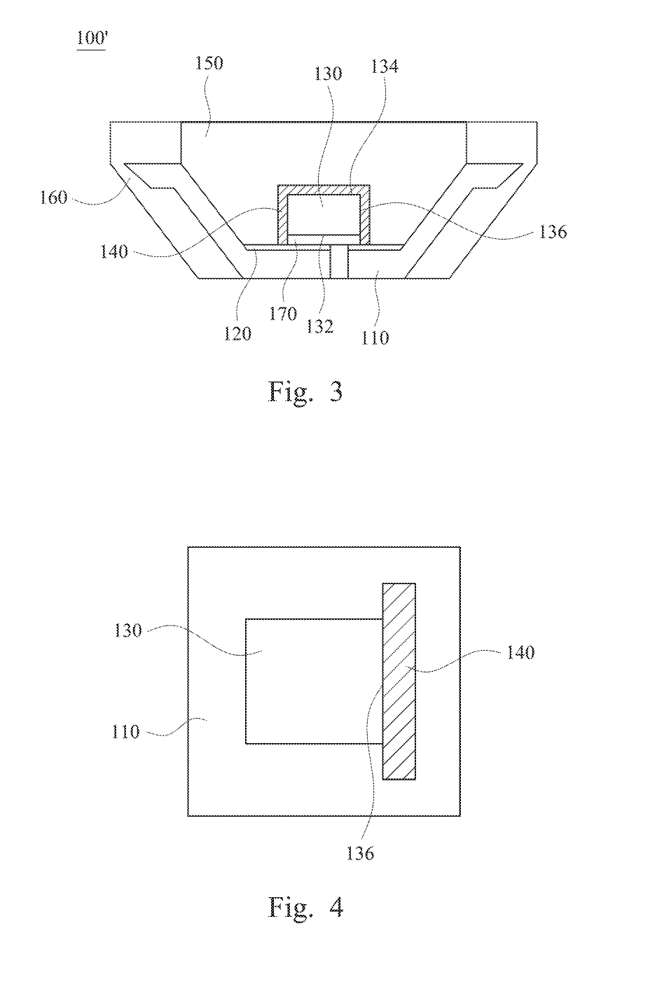

FIG. 3 illustrates a sectional view of a light emitting module 100′ according to another embodiment of the present disclosure. In an embodiment of the present disclosure, the light emitting diode chip 130 of the light emitting module 100′ is bonded on the die-bonding zone 120 with the upper surface 132. The transparent thermoplastic layer 140 entirely encloses the lower surface 134 and the side surfaces 136 of the light emitting diode chip 130. In this embodiment, the method of bonding the light emitting diode chip 130 is referred to a flip chip method, in which the base board 110 and the upper surface 132 are electrically connected with the bonding material 170. In an embodiment, the package cup body 160 is made of a thermoplastic material or a thermoset material. The thermoplastic material may be polycarbonate, polyethylene, polyethylene terephthalate, polybutylene terephthalate, poly 1,4-cyclohexylene dimethylene terephthalate, polycarbonate, polypropylene, nylon, or combinations thereof. The thermoset material may be silicone, epoxy, acrylate oracrylic, or combinations thereof. The transparent thermoplastic layer 140 may be polycarbonate, polyethylene, polyethylene terephthalate, polybutylene terephthalate, poly 1,4-cyclohexylene dimethylene terephthalate, polycarbonate, polypropylene, nylon, or combinations thereof. The fluorescent glue 150 includes fluorescent powder and a thermoplastic made of silicone, epoxy, acrylate, acrylic, or combinations thereof. In an embodiment, the fluorescent glue 150 further includes a light scattering material having less than 0.1 wt % of one of titanium dioxide, silica, zinc oxide, alumina, or combination thereof. In an embodiment, the transparent thermoplastic layer 140 is softened between 150 and 250 Celsius degrees and becomes a molten state. When the light emitting module 100′ undergoes a high temperature curing process, the fluorescent glue 150 expands upward. In the meantime, the transparent thermoplastic layer 140 is softened by heat, such that the transparent thermoplastic layer 140 becomes a buffer layer between the fluorescent glue 150 and the light emitting diode chip 130. When the fluorescent glue 150 expands upward, the light emitting diode chip 130 will not be pulled upward due to the buffer layer. Hence, the peeling-off phenomenon can be prevented.

FIG. 4 illustrates a top view of a light emitting module according to an embodiment of the present disclosure. In an embodiment, the transparent thermoplastic layer 140 is coated at a junction of the base board 110 and one side surface 136 of the light emitting diode chip 130, such that the bottom edge of one side surface 136 is enclosed by the transparent thermoplastic layer 140. When the light emitting module undergoes a high temperature curing process, the fluorescent glue expands upward. In the meantime, the transparent thermoplastic layer 140 is softened by heat, such that the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

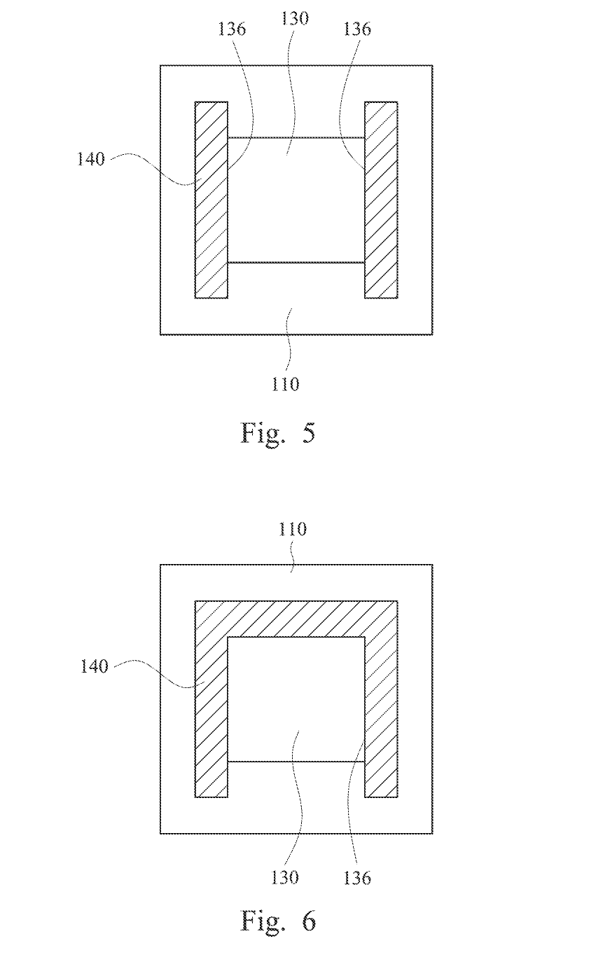

FIG. 5 illustrates a top view of a light emitting module according to another embodiment of the present disclosure. In an embodiment, the transparent thermoplastic layer 140 is coated at the junctions of the base board 110 and two side surfaces 136 of the light emitting diode chip 130, such that the bottom edges of two side surfaces 136 are enclosed by the transparent thermoplastic layer 140. When the light emitting module undergoes a high temperature curing process, the fluorescent glue expands upward. In the meantime, the transparent thermoplastic layer 140 is softened by heat, such that the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

FIG. 6 illustrates a top view of a light emitting module according to another embodiment of the present disclosure. In an embodiment of the present disclosure, the transparent thermoplastic layer 140 is coated at the junctions of the base board 110 and three side surfaces 136 of the light emitting diode chip 130, such that the bottom edges of three side surfaces 136 are enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

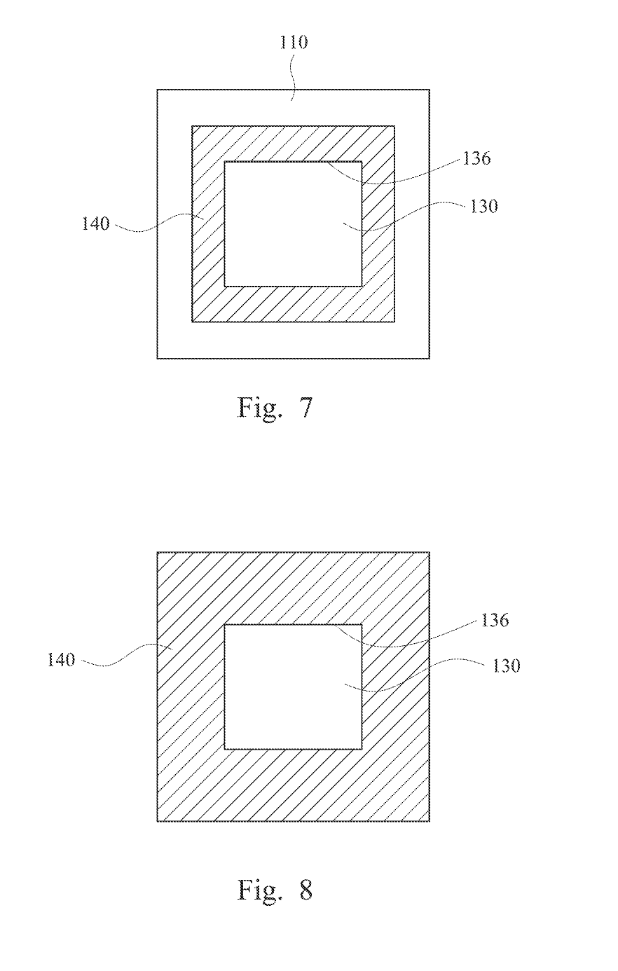

FIG. 7 illustrates a top view of a light emitting module according to another embodiment of the present disclosure. In an embodiment of the present disclosure, the transparent thermoplastic layer 140 is coated at the junctions of the base board 110 and all side surfaces 136 of the light emitting diode chip 130, such that the bottom edges of all side surfaces 136 are enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

FIG. 8 illustrates a top view of a light emitting module according to another embodiment of the present disclosure. In an embodiment of the present disclosure, the transparent thermoplastic layer 140 is coated at the junctions of the base board 110 and all side surfaces 136 of the light emitting diode chip 130, and the surfaces of the base board 110 near the light emitting diode chip 130, such that the bottom edges of all side surfaces 136 the surfaces of the base board 110 near the light emitting diode chip 130 are enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

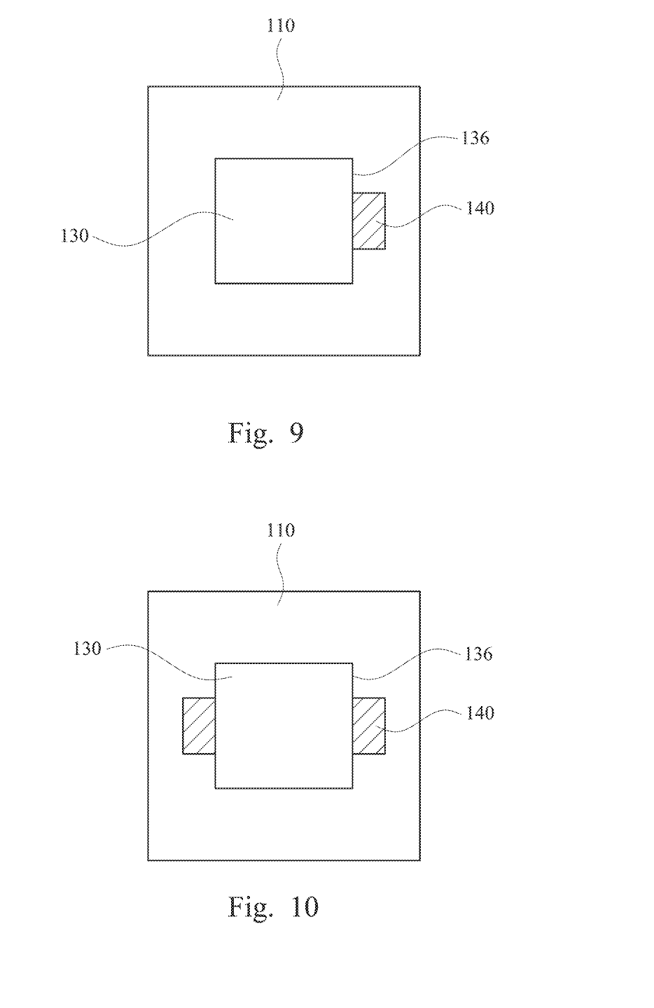

FIG. 9 illustrates a top view of a light emitting module according to another embodiment of the present disclosure. In an embodiment of the present disclosure, the transparent thermoplastic layer 140 is coated at a part of the junction of the base board 110 and one side surface 136 of the light emitting diode chip 130, such that a part of the bottom edge of one side surface 136 is enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

FIG. 10 illustrates a top view of a light emitting module according to another embodiment of the present disclosure. In an embodiment of the present disclosure, the transparent thermoplastic layer 140 is coated at parts of the junctions of the base board 110 and two side surfaces 136 of the light emitting diode chip 130, such that parts of the bottom edges of two side surfaces 136 are enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

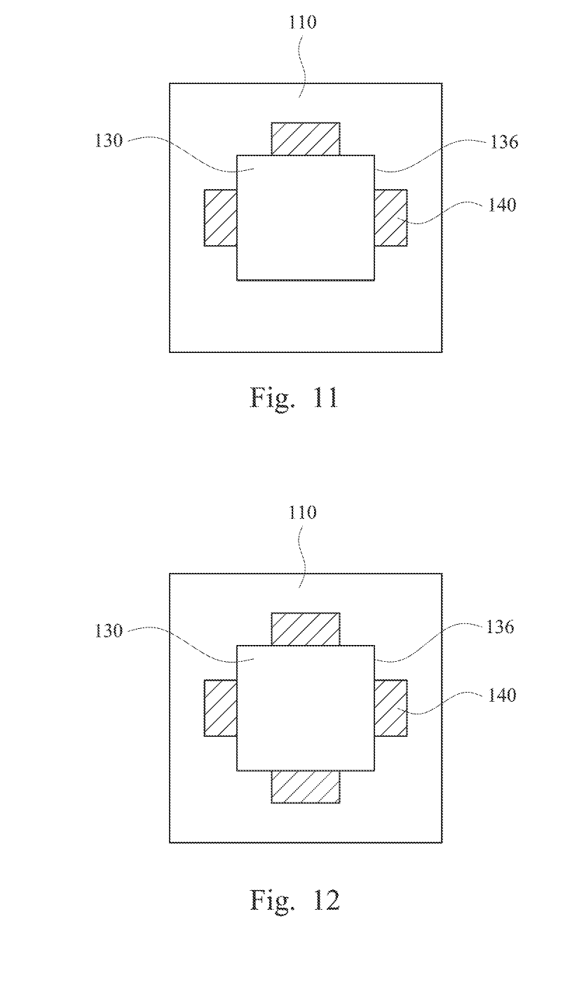

FIG. 11 illustrates a top view of a light emitting module according to another embodiment of the present disclosure. In an embodiment of the present disclosure, the transparent thermoplastic layer 140 is coated at parts of the junctions of the base board 110 and three side surfaces 136 of the light emitting diode chip 130, such that parts of the bottom edges of three side surfaces 136 are enclosed by the transparent thermoplastic layer 140. When the light emitting module undergoes a high temperature curing process, the fluorescent glue expands upward. In the meantime, the transparent thermoplastic layer 140 is softened by heat, such that, the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

FIG. 12 illustrates a top view of a light emitting module according to another embodiment of the present disclosure. In an embodiment of the present disclosure, the transparent thermoplastic layer 140 is coated at part of the junctions of the base board 110 and all side surfaces 136 of the light emitting diode chip 130, such that parts of the bottom edges of all side surfaces 136 and the base board 110 near thereof are enclosed by the transparent thermoplastic layer 140. When the light emitting module undergoes a high temperature curing process, the fluorescent glue expands upward. In the meantime, the transparent thermoplastic layer 140 is softened by heat, such that the transparent thermoplastic layer 140 becomes a buffer layer between the fluorescent glue and the light emitting diode chip 130. When the fluorescent glue expands upward, the light emitting diode chip 130 will not be pulled upward due to the buffer layer. Hence, the peeling-off phenomenon can be prevented.

Accordingly, the light emitting module of the disclosure includes the transparent thermoplastic layer. When the light emitting module goes through a curing process, the fluorescent glue expands upward. In the meantime, the transparent thermoplastic layer is softened by heat, such that the transparent thermoplastic layer becomes a buffer layer between the fluorescent glue and the light emitting diode chip. When the fluorescent glue expands upward, the light emitting diode chip will not be pulled upward due to the buffer layer, thus preventing a peeling-off phenomenon. As a result, the production yield is increased and the production cost is decreased.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting module, comprising:
a base board comprising a die-bonding zone which is predetermined;
a light emitting diode chip bonded on the die-bonding zone, the light emitting diode chip comprising an upper surface, a lower surface opposite to the upper surface, and a plurality of side surfaces adjoining to each other between the upper surface and lower surface;
a transparent thermoplastic layer enclosing at least one portion of the light emitting diode chip; and
a fluorescent glue disposed over to cover the base board, the light emitting diode chip, and the transparent thermoplastic layer.

2. The light emitting module of claim 1, wherein the base board is a metal frame.

3. The light emitting module of claim 2, further comprising a package cup body partially enclosing the metal frame and exposing a portion of a surface of the metal frame to be used as the die-bonding zone.

4. The light emitting module of claim 1, further comprising a bonding material used to bond the light emitting diode chip on the die-bonding zone, the bonding material comprising tin, copper-tin alloy, or gold-tin alloy.

5. The light emitting module of claim 1, wherein, when the light emitting diode chip is bonded on the die-bonding zone through the upper surface of the light emitting diode chip, the transparent thermoplastic layer fully encloses the lower surface and the side surfaces of the light emitting diode chip, and when the light emitting diode chip is bonded on the die-bonding zone through the lower surface of the light emitting diode chip, the transparent thermoplastic layer fully encloses the upper surface and the side surfaces of the light emitting diode chip.

6. The light emitting module of claim 1, wherein, when the transparent thermoplastic layer partially encloses the light emitting diode chip, the transparent thermoplastic layer is coated at a junction of the base board and at least one of the side surfaces of the light emitting diode chip, such that at least one portion of a bottom edge of the at least one of the side surfaces and a surface of the base board adjacent to the bottom edge are enclosed by the transparent thermoplastic layer.

7. The light emitting module of claim 3, wherein the package cup body is made of a thermoplastic material or a thermoset material.

8. The light emitting module of claim 7, wherein the thermoplastic material is selected from the group consisting of polycarbonate, polyethylene, polyethylene terephthalate, polybutylene terephthalate, poly 1,4-cyclohexylene dimethylene terephthalate, polycarbonate, polypropylene, nylon, and combinations thereof.

9. The light emitting module of claim 7, wherein the thermoset material is selected from the group consisting of silicone, epoxy, acrylate, acrylic, and combinations thereof.

10. The light emitting module of claim 1, wherein the transparent thermoplastic layer is selected from the group consisting of polycarbonate, polyethylene, polyethylene terephthalate, polybutylene terephthalate, poly 1,4-cyclohexylene dimethylene terephthalate, polycarbonate, polypropylene, nylon, and combinations thereof.

11. The light emitting module of claim 10, wherein the fluorescent glue comprises fluorescent powder and a thermoplastic selected from the groups consisting of silicone, epoxy, acrylate, acrylic, and combinations thereof.

12. The light emitting module of claim 11, wherein the fluorescent glue further comprises a light scattering material having less than 0.1 wt % of one of titanium dioxide, silica, zinc oxide, alumina, or combination thereof.
